(19) United States
(12) Patent Application Publication
(10) Pub. No.: US 2003/0056367 A1
(43) Pub. Date: Mar. 27, 2003

(54) Method and apparatus for reducing the flare in a flex cable

(76) Inventors: Kelly J. Reasoner, Ft. Collins, CO (US); Lyle D. Frey, Loveland, CO (US)

Correspondence Address: HEWLETT-PACKARD COMPANY, Intellectual Property Administration, P.O. Box 272400, Fort Collins, CO, 80527-2400, US

(21) Appl. No.: 09/963,227

(22) Filed: Sep. 25, 2001

(51) Int. Cl. H01R 3/00; H05K 3/00; B23P 19/00

(52) U.S. Cl. 29/857; 29/829; 29/745; 29/729

(57) ABSTRACT

A method and apparatus that reduces flaring in a flex cable.

### FIELD OF THE INVENTION

The present invention relates generally to flexible cables and more specifically to a method and device for reducing the flare in the flexible cable.

### BACKGROUND OF THE INVENTION

Flex cables, flexible circuits, flex harnesses, and flexible printed wiring are all names for electronic traces embedded in a flexible non-conductive material. Ribbon cables are typically multiple wires connected by their edges to form a strip of wires. Both flex circuits and ribbon cables are used to route electronic signals. In this application the term flex cable will be construed to cover both flex circuits and ribbon cables.

Many devices currently use flex cables to connect different electronic components. In some devices the flex cables turn corners to connect devices that are not co-linear. Some of these devices contain moving parts. When flex cables are attached to the moving parts or are near a moving part, care must be taken to ensure that the flex cable is not caught by the relative motion between the parts. If the flex cable is caught by a moving part the flex cable can be torn or damaged. Flex cables that turn corners have a higher likelihood of getting caught than flex cables that run in straight lines. Typically the flex cables that turn corners get caught on the outer radius of the bend that forms the corner. The tendency of a flex cable that has a corner or bend in it to stick up is called flaring.

One of the current solutions to this flaring problem is to attach a piece of double-sided tape under the flex cable to help hold the corner of the flex cable down. Unfortunately double-sided tape is an additional part and does not work well in some environments. What is needed is a method and apparatus that reduces the flaring in flex cables without double-sided tape.

### SUMMARY OF THE INVENTION

A method and device for reducing flaring when using flex cables.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a perspective view of a prior art flex cable attached to a device having relative motion between parts.

FIG. 2 is a drawing of a flex cable with a 90 preset angle.

FIG. 3 is a drawing of a flex cable in accordance with the present invention with a preset angle of 102 degrees.

FIG. 4 is a perspective view of a flex cable in accordance with the present invention attached to a device having relative motion between parts.

FIG. 5 is a perspective view of a flex cable in accordance with the present invention shown in its bent condition.

FIG. 6 is a drawing of a flex cable in accordance with the present invention with a preset angle of 78 degrees.

FIG. 7 is a perspective view of a flex cable in accordance with the present invention with a required angle less than 90 degrees.

### DETAILED DESCRIPTION OF THE PREFERRED EMBODIMENT

A method and apparatus that reduces flaring in a flex cable without double-sided tape can reduce the number of parts required for the assembly.

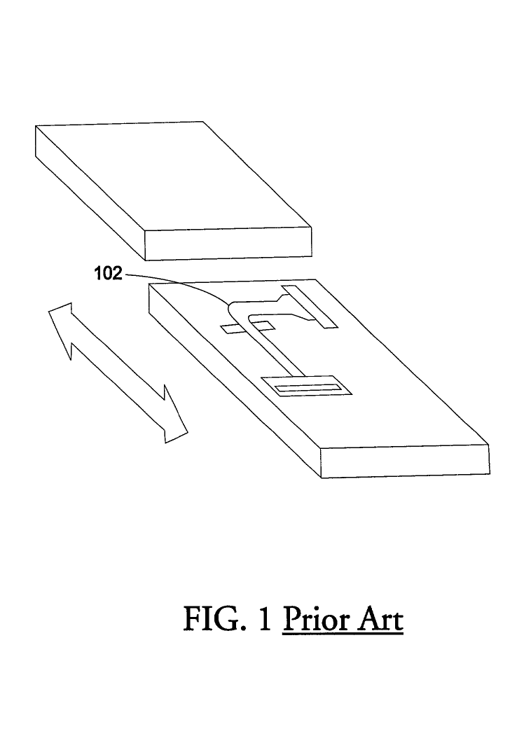

Auto-changers are typically large storage devices that contain many individual storage mediums, for example tapes, or RWCD's or DVD's. In this application a tape auto-changer will be used as an example but any type of storage medium could be used. In a tape auto-changer the tapes are typically kept in an array of racks and a picker is typically used to retrieve a tape and move it to one of the tape drives in the auto-changer. The picker typically has a number of electronic components attached to the picker. Some of these components may be connected using flex cables. Because of the tight tolerances between the picker and the auto-changer, any flex cable used on the outer surface of the picker is in danger of being damaged if it lifts away from the outer surface. Typically flex cables that run in a straight line do not lift away from the surface. However, flex cables that turn comers do have a tendency to lift away from the outer surface of the picker. This tendency to flare is dependent on the installation of the flex cable and can vary from assembly to assembly. Typically the flex cables flare or lift away from the surface at the outer radius of the corner (see 102). This flaring can cause the flex cable to be caught and damaged when the picker moves relative to the auto-changer body (see FIG. 1).

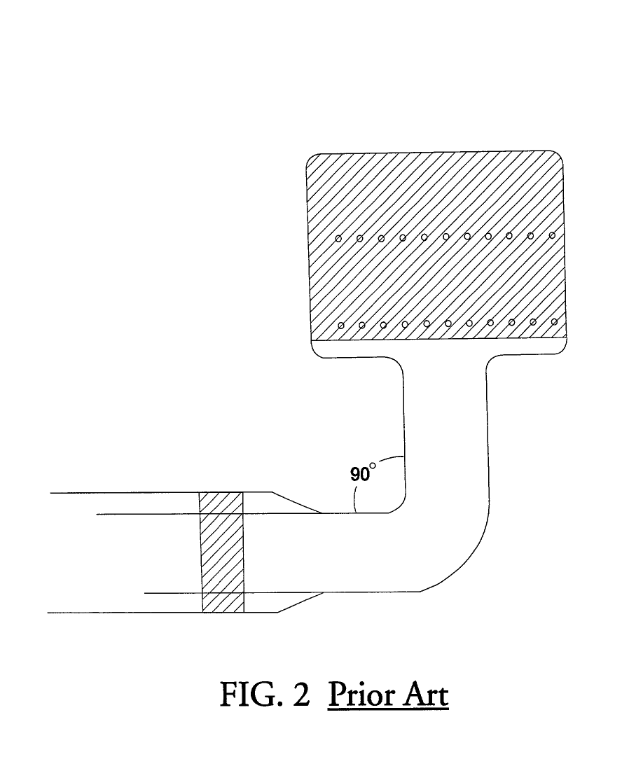

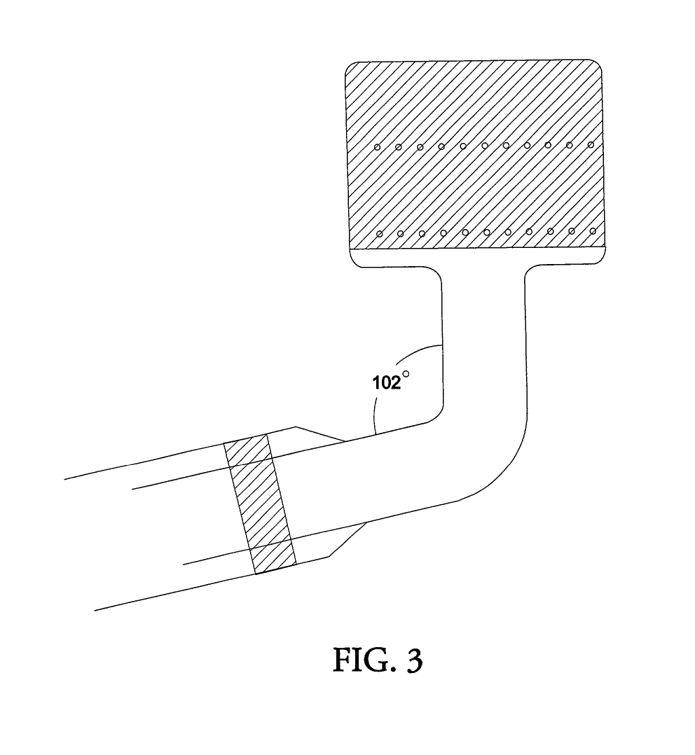

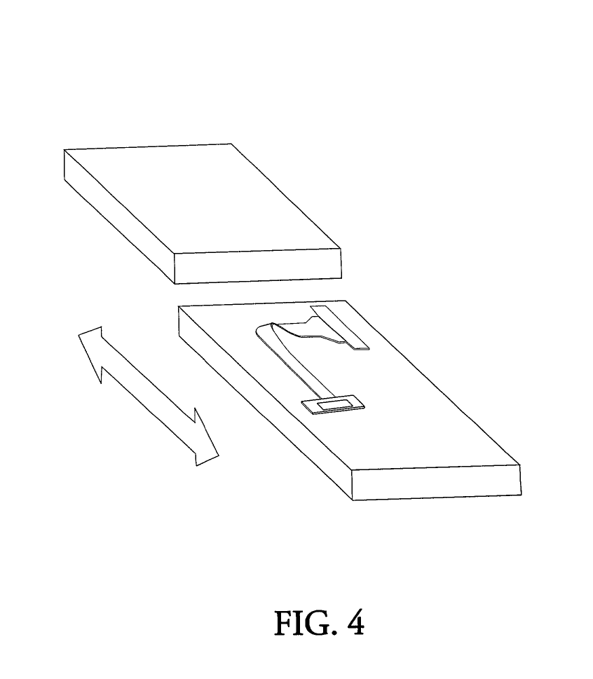

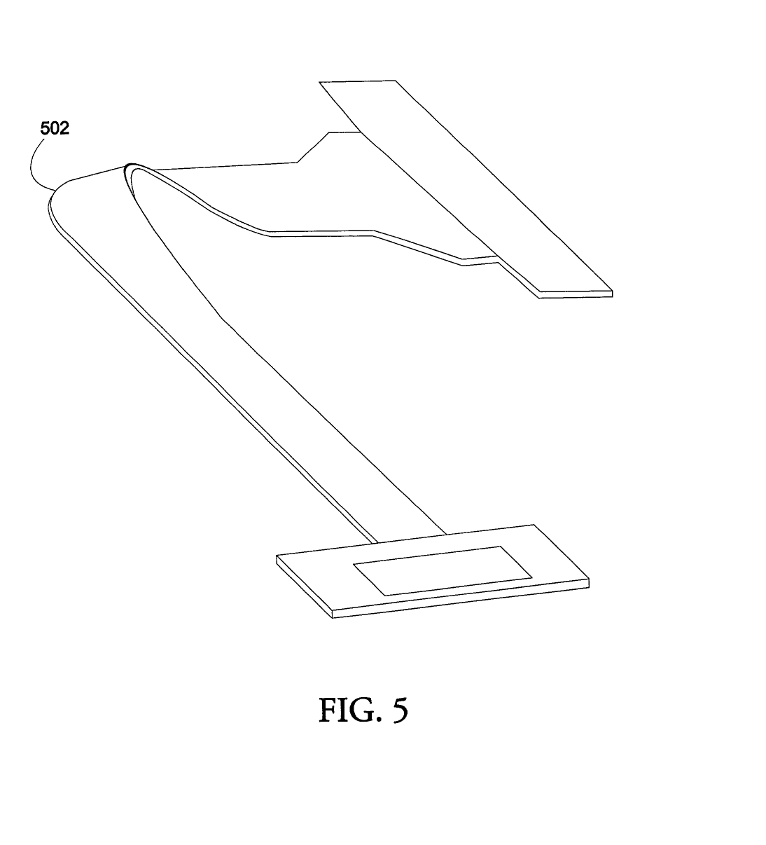

FIG. 2 shows an example flex cable with a preset angle forming a 90-degree corner. FIG. 3 shows an example embodiment of the current invention. The flex cable of the current invention has been modified from the flex cable in FIG. 2 by changing the preset angle from 90 degrees to 102 degrees, a 12-degree change in the preset angle. The required angle between the components connected by the flex cable has not changed and is still 90 degrees. The preset angle in the flex cable has been changed to something other than the required angle. In actual use the flex cable with the preset angle of 102 degrees is bent to form a 90-degree corner and then connected in its bent condition (see FIG. 4). By bending the flex cable beyond its preset angle, the outer radius of the corner 502 is forced downward and out of the plane formed by the flex cable in its relaxed condition (see FIG. 5). By forcing the outer radius down towards the picker, the flex cable in this embodiment of the current invention has reduced the tendency to flare in the flex cable.

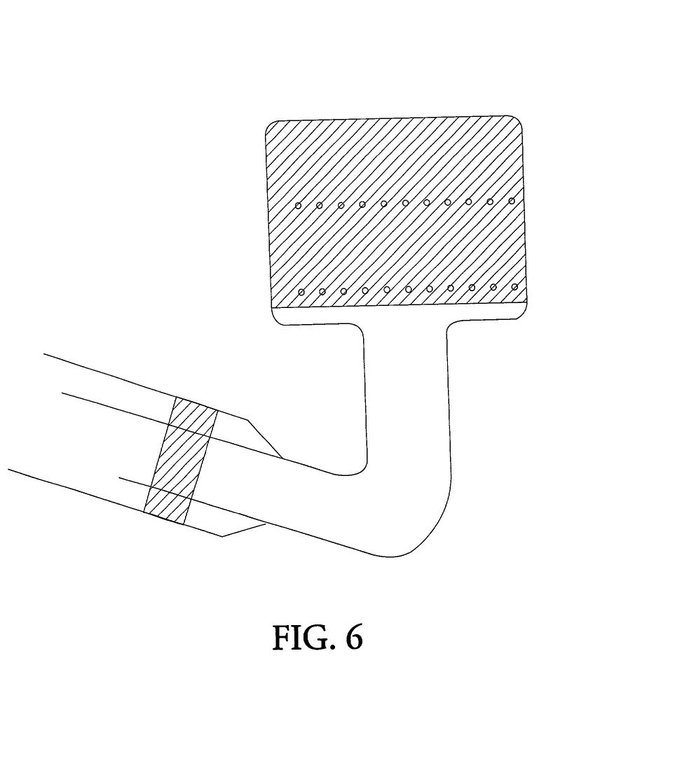

A 12-degree change in the preset angle forming the corner of the flex cable is the preferred embodiment of the current invention, however a wide range of angle changes will also work. Increasing the preset angle from the required angle is also the preferred embodiment of the current invention, for example increasing the angle from 90-degrees to 102-degrees. However a decrease in preset angle will also work, for example decreasing the preset angle from 90-degrees to 78-degrees (see FIG. 6). When the preset angle is decrease, the flex cable is bent beyond the preset angle in the opposite direction during use.

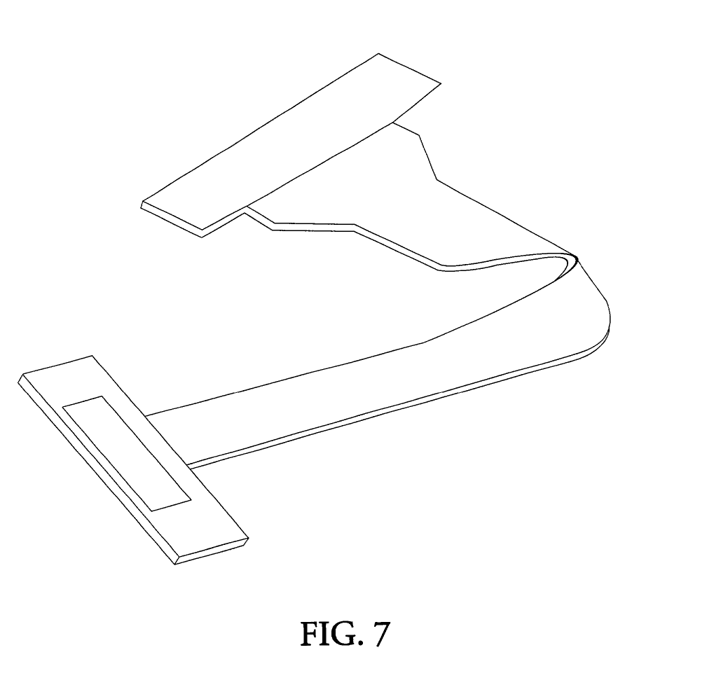

In the above examples, the required angle forming the comer in the flex cable was 90-degrees. The current invention is not limited to required angles of 90-degrees, but will work over a wide range of required angles (see FIG. 7). For example the required angle could be anywhere between almost zero to almost 180-degrees.

In the above examples a picker in an auto-changer was used to illustrate parts containing flex cables that have relative motion. The current invention is not limited to auto-changer but will be effective for flex cables used in any devices. The current invention is not limited to flex cables on parts having relative motion. Using the current invention can ease the assembly of devices that do not have relative motion. By reducing the flare in the flex cables, the current invention can minimize damage to flex cables during the assembly of a device that has no relative motion during actual use.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to clearly explain the principles of the invention and its practical application to thereby enable others skilled in the art to utilize the invention in various embodiments and various modifications as are suited to the particular use contemplated. It is intended that the appended claims be construed to include other alternative embodiments of the invention except insofar as limited by the prior art.

What is claimed is:

1. A method of connecting a flex cable, comprising:
bending the flex cable beyond a non-zero preset angle in the flex cable, without folding the flex cable, and;
connecting the bent flex cable.

2. The method of claim 1 where the flex cable is bent in a range between 4 and 20 degrees beyond its preset angle.

3. The method of claim 1 where the flex cable is bent approximately 12 degrees beyond its preset angle.

4. The method of claim 1 where the flex cable forms approximately a 90 degrees angle after it has been connected.

5. The method of claim 1 where, before bending, the flex cable is contained in approximately one plane.

6. A method of connecting a flex cable on a movable picker, comprising:
bending the flex cable past a preset angle in the flex cable, without folding the flex cable, and;
connecting the bent flex cable to the movable picker, whereby an outer radius of the preset angle is bent towards the movable picker.

7. A method of connecting a flex cable, comprising:
forming a curve in an inner radius of a bend in the flex cable, without folding the flex cable, whereby an outer radius of the bend in the flex cable is forced out of the plane defined by a first end and a second end of the flex cable, and;
connecting the flex cable while maintaining the curved condition.

8. A method of producing a flex cable, comprising:
determining the required angle for a corner in the flex cable;
fabricating a flex cable with a corner in the flex cable with an different angle than the required angle.

9. The method of claim 8 where the angle is different in the range between 4 and 20 degrees.

10. The method of claim 8 where the angle is different by approximately 12 degrees.

11. The method of claim 8 where the required angle is approximately 90 degrees.

12. The method of claim 8 where the fabricated angle is larger than the required angle.

13. The method of claim 8 where the fabricated angle is smaller than the required angle.

14. The method of claim 8 where the fabricated flex cable resides in approximately one plane.

15. An assembly, comprising:
a movable device, the movable device having a first surface;
a flex cable with a first end, and a second end, the first end forming a preset angle with respect to the second end, the preset angle being in a plane whereby the first end and the second end are still in a common plane, the preset angle forming an outer radius in the flex cable;
the first end and the second end of the flex cable are attached to the first surface of the movable device, in the attached state the first end of the flex cable forms an angle with respect to the second end of the flex cable that is different than the preset angle, whereby the outer radius of the flex cable is directed towards the first surface of the movable device.

16. The assembly of claim 15 where the difference in the preset angle and the attached angle is between the range of 4 and 20 degrees.

17. The assembly of claim 15 where the difference in the preset angle and the attached angle is approximately 12 degrees.

18. The assembly of claim 15 where the preset angle is approximately 90 degrees.

19. The assembly of claim 15 where the movable device is a picker in an auto-changer.
